(19) United States
(12) Patent Application Publication
(10) Pub. No.: US 2026/0346522 A1
(43) Pub. Date: Nov. 5, 2026

(54) Method and System for Temperature Pre-Conditioning a Mould Cavity of a Mould for Encapsulating Electronic Components

(71) Applicant: Besi Netherlands B.V., Duiven (NL)

(72) Inventors: Joannes Leonardus Jurrian Zijl, Ede (NL); Albertus Franciscus Gerardus van Driel, Lobith (NL); Jan Roelofsen, Zevenaar (NL); Sebastianus Hubertus Maria Kersjes, Lent (NL); Wilhelmus Gerardus Joseph Gal, Braamt (NL)

(21) Appl. No.: 19/488,923

(22) PCT Filed: May 28, 2024
(86) PCT No.: PCT/NL2024/050270

§ 371 Date: Dec. 1, 2025

(30) Foreign Application Priority Data
Jun. 2, 2023 (NL) 2034976

(51) Int. Cl. B29C 45/73; B29C 45/78; B29L 31/34; H10W 74/01

(52) U.S. Cl. CPC B29C 45/7337; B29C 45/7306; B29C 45/78; H10W 74/016; B29C 2945/7604; B29C 2945/7626; B29C 2945/76531; B29C 2945/76739; B29L 2031/3406

(57) ABSTRACT

The present invention relates to method for pre-conditioning the temperature of a mould cavity of a mould for encapsulating electronic components, including the method steps: A) providing a mould for encapsulating electronic components comprising a mould cavity with a mould cavity wall, and B) injecting a temperature pre-conditioning gas into the mould cavity. The temperature of the temperature pre-conditioning gas prior to injecting the temperature pre-conditioning gas into the mould cavity is controlled to change the temperature of the mould cavity wall due to controlled temperature exchange with the temperature pre-conditioning gas to a desired temperature level. The present invention further relates to a system for pre-conditioning a mould cavity.

### CROSS-REFERENCE TO RELATED APPLICATIONS

This application is the United States national phase of International Patent Application No. PCT/NL2024/050270 filed May 28, 2024, and claims priority to The Netherlands Patent Application No. 2034976 filed Jun. 2, 2023, the disclosures of which are hereby incorporated by reference in their entireties.

### BACKGROUND OF THE INVENTION

### Field of The Invention

The present invention relates to a method for temperature pre-conditioning a mould cavity of a mould for encapsulating electronic components. The invention also relates to a system for temperature pre-conditioning such a mould cavity.

### Description of Related Art

Electronic components can be protected from their surroundings by at least partial encapsulation. In particular semiconductors mounted on a substrate, such as lead frames. Examples of semiconductors are chips, Light Emitting Diodes (LEDs), and other electronic components. Encapsulation prevents corrosion of these often delicate components and prevents damage due to mechanical impact. Encapsulation refers to creating a protective shell around electronic components by moulding a compound on and around the components. Different materials can be used for encapsulation and typically include a thermoset epoxy or resin with a filler.

Different types of encapsulating processes exist, such as transfer moulding, compression moulding and injection moulding. These encapsulation processes have in common that a substrate carrying the electronic components is clamped between two mould parts at least one of the two mould parts being provided with a mould cavity. As such, a mould cavity is formed around each electronic component to be encapsulated. A liquid encapsulating material is subsequently fed into these cavities and allowed to cure. After at least partial curing, or hardening of the liquid encapsulating material, the mould parts are separated and a substrate with encapsulated electronic components is removed from the mould.

During encapsulation, heat and pressure are typically exerted on the encapsulating material, liquifying the encapsulating material. The liquid encapsulating material fills the mould cavity, surrounding the electronic components. Thereafter, the liquid encapsulating material cures at least partially in the mould cavity. Curing normally is a result of cross-linking of the encapsulating polymer.

It is important that the electronic components are precisely encapsulated. Some parts of the substrate must be kept free from encapsulation material in order to connect further components to the substrate and also parts of the electronic components may remain free from encapsulating material. As semiconductor components are very small, incorrect or inaccurate encapsulation may lead to unacceptably large deviations from intended sizes of encapsulated electronic components or rejection due to improper encapsulation, e.g. due to the presence of inclusions. It is therefore necessary that the encapsulation material is on the one hand sufficiently liquid to fully fill the mould cavity, while on the other hand no excessive encapsulating material is to be brought into the mould cavity. Also moulding flash (encapsulating material entering between the mould halves or between the carrier of the electronic components and a mould half) is to be prevented. Flashing is also referred to as bleeding and can be mitigated by having not a too low viscosity of the encapsulating material, while on the other side a higher viscosity is required to have an even flow of encapsulation material in the mould cavity. In case a mould cavity is not completely filled with encapsulating material. Voids may remain in the encapsulating material. Also small bubbles of gas being trapped in the encapsulating material have to be avoided, as they also may create voids. To enhance the quality of encapsulation a negative pressure may be applied to the mould cavity prior and/or during the encapsulating process (negative pressure is a pressure below external air pressure). Such negative pressure may be applied through suction channels, referred to as ventings, which enable active or passive discharge of gases during the encapsulation. A negative air pressure in the mould cavity may decrease the formation of voids.

In DE 11 2012 004 392 B4 a method is disclosed for lowered pressure encapsulating electronic components mounted on a carrier, wherein an electronic component that is placed in a mould cavity is encapsulated by filling the mould cavity with liquid encapsulation material that is subsequently cured. To affect a lower pressure in the mould cavity in this publication is proposed that before the encapsulation material is brought into the mould cavity a volume reducing material is introduced into the mould cavity. The volume reducing material undergoes a phase change to minimize the material content in the mould cavity before or during the filling of the mould cavity with encapsulating material, and so to enhance the filling quality and reduce the chance of inclusions in the cured encapsulating material.

Nevertheless, despite all the efforts already done and due to the still enhancing quality demands for encapsulated electronic components there is a further demand to enhance the process control of the encapsulation of electronic components.

It is therefore an object of the present invention to provide a method and a system for encapsulating electronic components, wherein the quality of encapsulation of electronic components is further improved.

### SUMMARY OF THE INVENTION

The invention hereto provides a method for temperature pre-conditioning a mould cavity of a mould for encapsulating electronic components. Injection of the temperature pre-conditioning gas having a controlled temperature different from a temperature of the mould cavity wall, causes a transfer of heat from the temperature pre-conditioning gas to the mould cavity wall, or vice-versa. Typically heat is transferred from the temperature pre-conditioning gas to the mould cavity wall, i.e. the mould cavity wall is heated by the temperature pre-conditioning gas but also a cooling of the mould cavity wall could be effected if and when a mould cavity is too hot for ideal encapsulation. The mould cavity wall is to be interpreted as the part of the mould defining or bordering the mould cavity. As such, it is the mould cavity wall that contacts the temperature pre-conditioning gas after injecting the temperature pre-conditioning gas in the mould cavity. The temperature pre-conditioning gas has a controlled temperature before injection. This allows for a very accurate control of the temperature of the mould cavity wall just before the encapsulation material enters the mould cavity and as such an important process condition that is highly relevant for the encapsulation result is well controlled due to the use of the temperature-controlled conditioning gas. Of course the temperature of the mould cavity is for an important part steered by an electrical heating system incorporated in the mould parts. However, such heating system is not quick in responding to rapid and smaller changes in the surface temperature of the mould cavity/cavities. The surface temperature in the mould cavity may for instance suddenly change due to changing process conditions and/or environmental influences (e.g. temperature changes in the temperature of encapsulation material and/or carriers with electronic components in previous process cycles, environmental temperature changes, suddenly changing weather conditions, opening of the machine housing, draft and so on). With the present invention also smaller and suddenly arising temperature deviations (deviating from the ideal mould cavity wall temperature) may be eliminated. The temperature of the temperature pre-conditioning gas prior to injecting the temperature pre-conditioning gas into the mould cavity may be controlled on the basis of temperature detection and subsequently pre-calculating the require temperature of the pre-conditioning gas.

The total volume of temperature pre-conditioning gas that is to be used may also vary. Herein the volume is defined under standard temperature and pressure (STP). STP is defined as a temperature of 273.15 K and an absolute pressure of 1.105 Pa.

A further advantage of the present invention is that the heat transferred between the temperature pre-conditioning gas and the mould may also eliminate any temperature inhomogeneities existing over the mould cavity wall. This results in a (more) homogeneous temperature over the mould cavity wall and thus in a more homogeneous encapsulation result (i.e. a homogeneous quality of the encapsulated products). The injection of temperature pre-conditioning gas also ensures that any remaining (unwanted) gasses are removed from the mould cavity and thus the filling of the mould cavity is uniform and controlled. In addition, any particles or other contaminants may, at least partly, also be removed with the pre-conditioning gas.

Prior to injecting the temperature pre-conditioning gas in the mould cavity through the mould cavity entrance opening, the method may comprise providing a foil in the mould cavity. The temperature pre-conditioning gas also ensures the temperature control of the foil and may also reduce temperature inhomogeneities in the foil. The pressure of the temperature pre-conditioning gas may also be advantageously pushing the foil against the mould cavity wall.

With a further optimalisation also the total gas volume of the temperature pre-conditioning gas injected in the mould cavity may be controlled to change the temperature of the mould cavity wall with the temperature pre-conditioning gas to a desired temperature level. With the volume control of the temperature pre-conditioning gas also the heat capacity (or alternatively the cooling capacity) of the temperature pre-conditioning gas fed into the mould cavity is under control which is thus further supportive in controlling the process conditions of the mould cavity at the moment it is filled with encapsulating material.

Also the feed rate of the temperature pre-conditioning gas injected in the mould cavity may be controlled to change the temperature of the mould cavity with the temperature pre-conditioning gas in a controlled time-frame to a desired temperature level. With controlling the feed rate also the time component in the process control is present which is even more supportive for an enhance process control (ant thus and enhance control of the resulting encapsulated electronic components). A relatively high volumetric flow rate ensures that a temperature difference between the temperature pre-conditioning gas and the mould cavity wall stays large and thus the transfer rate of heat is higher than at lower flow rates.

The mould cavity may be filled with temperature precondition gas through at least one mould cavity opening, which opening may later be used as the entrance opening for the liquid encapsulating material. Such feed opening, or runner, may be embodied as an opening through a part of a mould halve surrounding the mould cavity. The temperature pre-conditioning gas may be fed to the mould cavity in a closed situation (wherein the mould halve are placed in a closed position with the electronic component to be incapsulated already in the mould cavity) or in an opened position wherein the mould cavity is still open due to as the mould halve are not brought in contact with each other (yet). Alternatively, the temperature pre-conditioning gas may also be introduced in the mould cavity through an already existing discharge opening connecting to the mould cavity, also referred to as a “venting”. Preferably, the temperature pre-conditioning gas enters the mould cavity through an entrance opening and leaves the mould cavity through a discharge opening. By controlling the feed and discharge of pre-conditioning gas also the pressure in the mould cavity is controllable which allows even more control of the heat transfer between the temperature pre-conditioning gas and the mould cavity wall. A higher pressure inside the mould cavity by an increased amount of temperature pre-conditioning gas within the mould cavity may increase the speed at which heat is transferred between the temperature pre-conditioning gas and the mould.

The temperature pre-conditioning gas may have a temperature of at least 50 °C, preferably at least 100 °C, more preferably at least 125 °C, even more preferably at least 150 °C, most preferably between 150 °C and 200 °C. Depending on the desired end temperature of the mould cavity wall the temperature of the temperature pre-conditioning gas may be set at a certain desired temperature.

The temperature pre-conditioning gas may also be a condensable gas. Condensable gas can undergo a phase change from a gas to liquid. When the temperature pre-conditioning gas has a temperature above a temperature of the mould cavity wall, the temperature pre-conditioning gas may condensate upon contacting the mould cavity wall. It is also possible that the temperature pre-conditioning gas undergoes a phase change from gas directly to solid (i.e. deposition), or from gas to liquid to solid (freezing). This exothermic process efficiently transfer heat from the temperature pre-conditioning gas to the mould cavity wall, however the remaining fraction may disturb the encapsulation process. In case use is made of phase change it is advantageous if the temperature pre-conditioning gas has a relatively low molecular weight, e.g. a molecular weight below 50 g/mol, such as 46 g/mol (ethanol), or more preferably below 25 g/mol, such as 18 g/mol (water), or even lower, such as below 15 g/mol or below 10 g/mol. As a phase change of the temperature pre-conditioning gas from a gas phase to a liquid phase occurs, a relatively low molecular weight advantageously reduces the volume to a large extent. In line therewith, the temperature pre-conditioning gas is preferably steam, ethanol gas, or a combination thereof, as these gases are condensable and have a relatively low molecular weight. The change of the temperature pre-conditioning gas to a phase having a higher density is exothermic reaction, and as such, energy is released. When this exothermic reaction takes place at the mould cavity wall, this energy, in the form of heat, is very efficiently transferred to the mould

In an embodiment wherein a foil is used in the mould, the liquid encapsulating material is normally fed between the substrate and the foil material and any temperature pre-conditioning gas may be brought into the mould cavity between the foil and the mould. In such an embodiment the encapsulating material is thus on the opposite side of the foil than the temperature pre-conditioning gas and the two will not contact with each other. The temperature pre-conditioning gas and the electronic components and encapsulating material are thus separated and will not influence each other. Yet another option is that the temperature pre-conditioning gas is fed into the mould cavity wherein a foil is already brought into contact with the mould cavity wall. The temperature pre-conditioning gas is contacting the foil on the side of the foil facing away from the mould cavity. In this embodiment, the foil may be pressed against the mould cavity wall due to pressure exerted by the temperature pre-conditioning gas. The heat exchange between the temperature pre-conditioning gas and the mould cavity wall thus has to pass the foil and is thus less efficient than when the temperature pre-conditioning gas directly contact the mould cavity wall.

Preferably, the ratio between the total volume of the temperature pre-conditioning gas after injecting and the total volume of the mould cavity is at least 5:1, preferably at least 10:1, more preferably at least 20:1, and most preferably at least 30:1. The larger the ratio volume temperature pre-conditioning gas/volume mould cavity is the more heat may be transferred and the more the temperature pre-conditioning gas may rinse the mould cavity as the temperature pre-conditioning gas may have a blowing effect.

Advantageously, prior to injecting the pre-conditioning gas, a temperature difference between the pre-conditioning gas and the mould cavity wall is less than 100 °C, preferably less than 50 °C, more preferably less than 20 °C, most preferably less than 5 °C. This may prevent temperature shock and/or may prevent the temperature pre-conditioning gas to condensates in the mould cavity.

In a beneficial embodiment, the temperature change of the mould cavity wall is such that the resulting temperature is substantially homogeneously distributed over the wall surface. This is an important additional advantage of the present invention; any temperature differences over the mould cavity wall-which are from a point of process control absolutely not desired-may be reduced, or even better levelled out, due to the temperature exchange of the mould cavity wall with the pre-conditioning gas. An additional effect of the use of the temperature pre-conditioning gas is thus that also less or no temperature differences over the surface of the mould cavity wall will remain.

Preferably, the method step A) providing a mould comprising a mould cavity and at least one mould cavity opening comprises moving a first mould part and a second mould part towards each other, and contacting at least part of the first mould part with the second mould part and/or clamping a carrier with electronic components between the mould halves to obtain a substantially enclosed mould cavity. In a specific embodiment the mould cavity may be substantially closed and at least one electronic component carried by a substrate may be allocated in the mould cavity before the temperature pre-conditioning gas contacts the cavity wall. The method is in particular effective in the situation wherein a mould cavity is substantially closed while the temperature pre-conditioning gas contacts the mould cavity wall as the contact of the pre-conditioning gas with the mould cavity wall will in such a situation be very effective. In such a situation the pre-conditioning gas may be fed into the mould cavity though a mould cavity entrance opening and may at least partly exit the mould cavity through a mould cavity exit opening. The feed and discharge openings of the mould cavity provided for feeding the encapsulation material and for venting the mould cavity may also be used for the feed and discharge of the temperature pre-conditioning gas. In the situation wherein (a part of) the substrate and at least one electronic component are allocated in the mould cavity during the injection of the temperature pre-conditioning gas in the mould cavity not only the temperature of the mould cavity wall is controlled but also the temperature of the part of the substrate and the electronic component(s) in the mould cavity is controlled. As a result, behaviour of the encapsulation material during the moulding process is even more predictable as the temperature of all the surfaces (mould cavity, substrate, electronic component(s)) may be homogenously controlled. As a result, the quality of encapsulation will be better due to a (nearly) full control of the viscosity of the encapsulation material during the moulding process.

As an alternative the temperature of the mould cavity many also be modified with a temperature-controlled pre-conditioning gas in a situation wherein the mould cavity is open (this before closing the mould cavity around at least one electronic component carried by a substrate). In such a situation it is easier to bring (larger volumes) of temperature pre-conditioning gas in a short time frame into contact with the mould cavity wall.

A contact time of the pre-conditioning gas and the mould cavity wall may be at least 0.1, at least 0.5, at least 1, at least 2 or at least 5 seconds. A longer contact time will be supportive to affect a homogenized temperature of the mould cavity wall.

In an embodiment, a temperature of at least part of the mould cavity wall is measured at at least two different locations providing at least two temperature measurements, and wherein the contact time of the temperature pre-conditioning gas mould cavity wall is controlled based on the temperature measurements. Measuring a temperature at two different locations provides information of not only the temperature but also of the (in)homogeneity of the temperature distribution over the mould cavity wall. This information may be used to control for instance the temperature, the volume and the duration of the mould cavity wall processing with temperature pre-conditioning gas.

The present invention also provides a system for temperature pre-conditioning a mould cavity. For the advantages of the system according to the present invention reference is made to the advantages of the method according to the present invention as listed above.

Preferably, the system comprises at least one but preferably at least two temperature sensors located in the mould cavity wall. A single sensor enables to provide temperature information to an automatic process control but with temperature measurements at at least two different locations also information is available on the temperature homogeneously of the mould cavity wall. These measurements, and potentially also a difference between plural temperature measurements, enable to (automatically) control the required temperature pre-conditioning process.

The system may comprise a heater for heating the injector fed temperature pre-conditioning gas. The temperature pre-conditioning gas may be injected in the mould cavity as a gas but also alternatives are possible, like for instance a superheated liquid or a steam.

In line with the above, the system may comprise a controller for controlling the volumetric flow rate and/or temperature of the pre-conditioning gas injector. The controller may control the volumetric flow rate and/or temperature of the temperature pre-conditioning gas based on one or more temperature measurements.

### BRIEF DESCRIPTION OF THE DRAWINGS

The terms Fig., Figs., Figure, and Figures are used interchangeably in the specification to refer to the corresponding figures in the drawings.

The invention will hereinafter be further elucidated on the basis of the following non-limitative exemplary embodiments. Herein shows:

FIG. 1A—a cross-sectional view of a non-conditioned mould cavity;

FIG. 1B—a cross-sectional view of the mould cavity being pre-conditioned;

FIG. 1C—a cross-sectional view of the mould cavity wherein electronic components are encapsulated;

FIG. 1D—a cross-sectional view of the mould cavity including electronic components being pre-conditioned;

FIG. 2A—a cross-sectional view of a non-conditioned mould cavity including foil layers;

FIG. 2B—a cross-sectional view of the mould cavity with foil layers being pre-conditioned; and

FIG. 3—a system for pre-conditioning a mould cavity.

### DESCRIPTION OF THE INVENTION

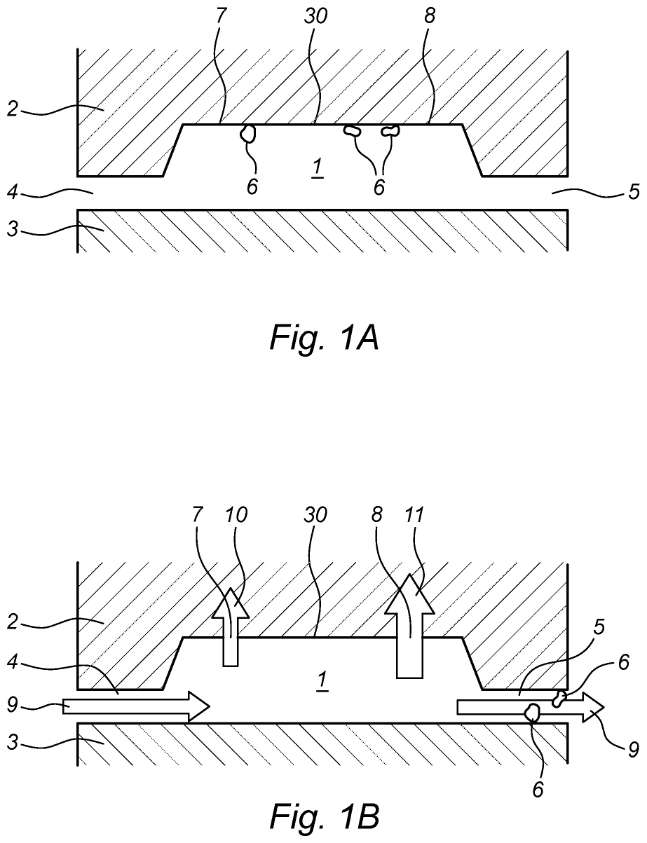

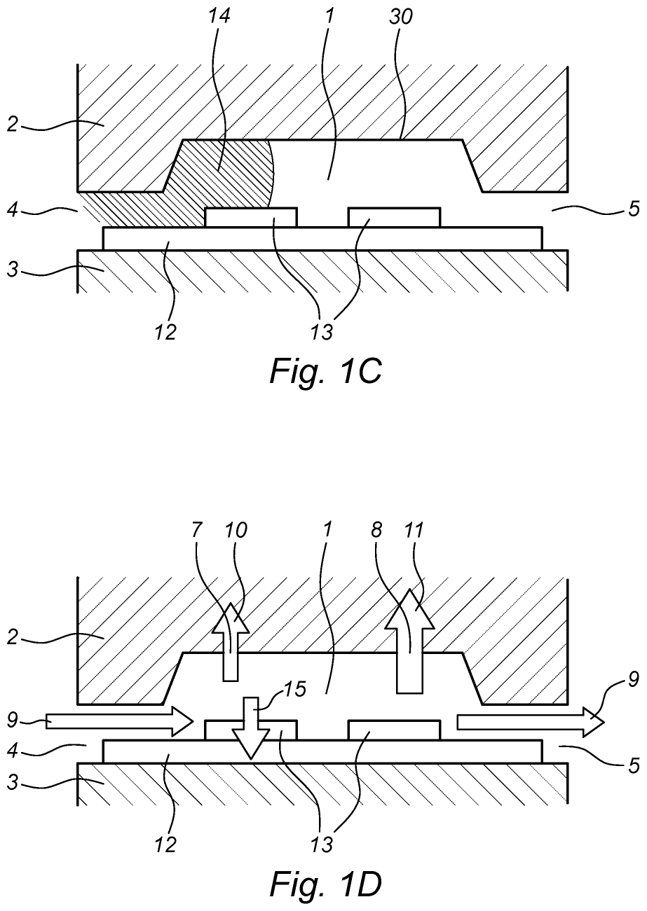

FIG. 1A shows a cross-sectional view of a mould cavity 1 with a mould cavity wall 30 formed between an upper mould part 2 and a lower mould part 3. The mould cavity 1 has a mould cavity entrance opening 4 and a mould cavity exit opening 5. The mould cavity wall 30 is not pre-conditioned and to the mould cavity wall 30 some small debris particles 6 are attached. The temperature of the mould cavity wall 30 is inhomogeneous as the temperature of the mould cavity wall 30 at a first location 7 is lower than a temperature of the mould cavity wall 30 at a second location 8.

FIG. 1B shows the same mould cavity 1 as in FIG. 1A wherein a temperature pre-conditioning gas 9, represented with an arrow, enters the mould cavity 1 via the mould cavity entrance opening 4 and exits the mould cavity 1 via the mould cavity exit opening 5. The flow of the temperature pre-conditioning gas 9 through the mould cavity 1 ensures that the debris particles 6 are dislodged cleaning the mould cavity wall 30 and the debris particles 6 are subsequently removed out of the mould cavity 1 by the temperature pre-conditioning gas 9. The temperature pre-conditioning gas 9 has a temperature that differs from the temperature of the of the mould cavity wall 30 at the first and second locations 7, 8. Due to the temperature difference between the temperature pre-conditioning gas 9 and of the mould cavity wall 30 at the first and second locations 7, 8, heat is transferred (arrows 10 and 11) from the temperature pre-conditioning gas 9 to (or alternatively when cooling away from) the mould cavity wall 30 at the first and second locations 7, 8. The heat transfer 10 from (or to) the temperature pre-conditioning gas 9 to at first location 7 may for instance be less than the heat transfer 11 from (or to) the temperature pre-conditioning gas 9 at the second location 8, due to the temperature difference, and thus the driving force, between the temperature pre-conditioning gas 9 and the second location 8 being larger as compared to the temperature difference between the temperature pre-conditioning gas 9 and the first location 7. In case the flow of the temperature pre-conditioning gas 9 through the mould cavity 1 is relatively high the temperature of the temperature pre-conditioning gas 9 may therefore assumed to be constant throughout the mould cavity 1.

FIG. 1C shows the mould cavity 1 of FIGS. 1A and 1B after pre-conditioning. A substrate 12 with electronic components 13 has been placed in the mould cavity 1 and rests on the lower mould part 3. Liquid encapsulating material 14 is fed through the mould cavity entrance opening 4 and pushes any remaining temperature pre-conditioning gas 9 out of the mould cavity 1 via the mould cavity exit opening 5. Ideally the mould cavity wall 30 may be pre-conditioned at a temperature equal to the temperature of the encapsulating material 14, so that hardly any heat exchange between the encapsulating material 14 and the mould cavity wall 30 will occur.

FIG. 1D shows the mould cavity 1 of FIGS. 1A-1C wherein the substrate 12 with electronic components 13 is placed prior to pre-conditioning of the mould cavity 1 between the mould parts 2,3 such that the electronic components 13 are allocated in the mould cavity 1. The temperature pre-conditioning gas 9 entering the mould cavity 1 via the mould cavity entrance opening 4 and leaving the mould cavity 1 via the mould cavity exit opening 5 transfers heat to (or from) the mould cavity wall 30 but potentially also to (or form) a part of the substrate 12 and the electronic components 13. As the temperature of the mould cavity wall 30 at the first location 7 may be higher than the temperature of the mould cavity wall 30 at the second location 8, more heat is transferred from (or to) the temperature pre-conditioning gas 9 at the second location 8, compared to the first location 7. In addition, heat is transferred 15 to (or from) the electronic components 13 and a part of the substrate 12, which may have an inhomogeneous temperature distribution prior to the temperature pre-conditioning as well. As such, not only the mould cavity 1 is temperature pre-conditioned, but also the substrate 12 and electronic components 13 are temperature pre-conditioned as well. In the case of compression moulding, it is also conceivable to temperature pre-condition the encapsulating material 14 as well, by placing the encapsulating material in the mould cavity 1 and heating or colling it as well with the temperature pre-conditioning gas 9.

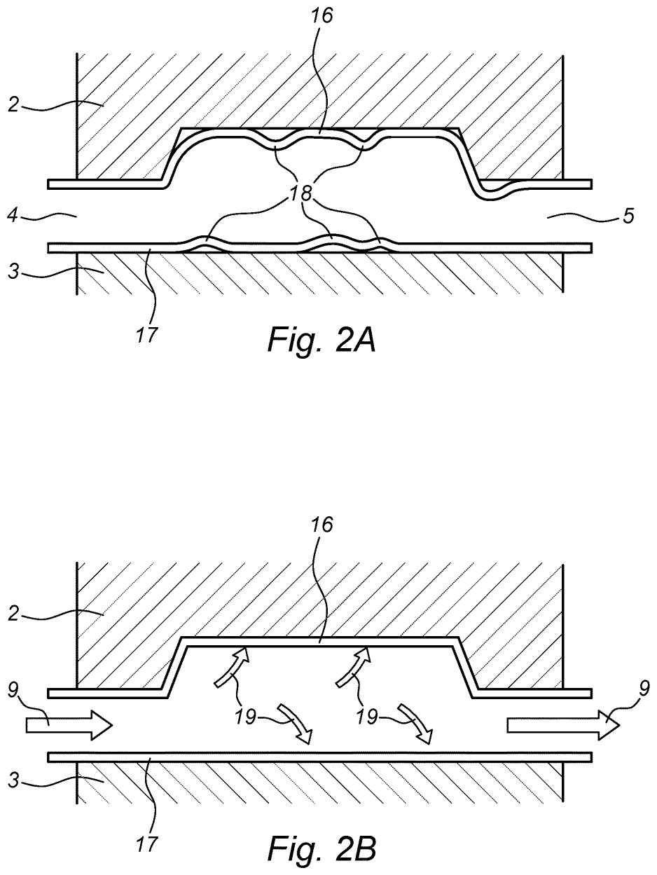

FIG. 2A shows the mould cavity 1 of FIGS. 1A-1D, with a top foil layer 16 in the mould cavity 1 and a bottom foil layer 17 placed on the upper mould part 2 and the lower mould part 3, respectively. Both foil layers 16, 17 are not optimally aligned with their respective mould parts 2, 3. The foil layers 16, 17 contain small wrinkles 18, that negatively affect the encapsulating process. As can be seen in FIG. 2B, forcing a temperature pre-conditioning gas 9 through the mould cavity entrance opening 4, exerts pressure 19 from the temperature pre-conditioning gas 9 onto the foil layers 16, 17 towards the upper mould part 2 and the lower mould part 3. As such, the foil layers 16, 17 are smoothened and the wrinkles 18 are reduced. By restricting flow of the temperature pre-conditioning gas 9 through the mould cavity exit opening 5, the pressure exerted by the temperature pre-conditioning gas 9 can be adjusted such that the foil layers 16, 17 are optimally smoothed.

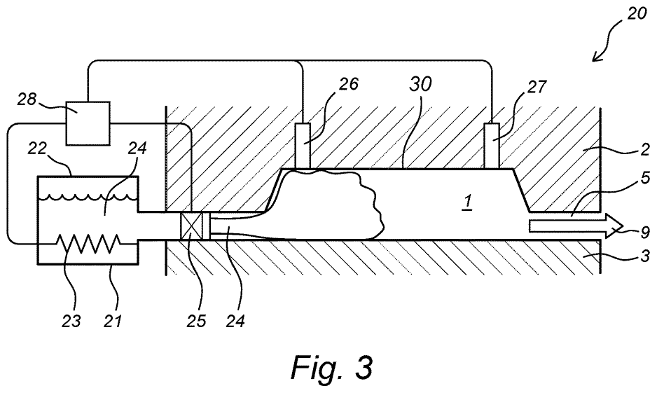

FIG. 3 shows a system 20 for pre-conditioning a mould cavity 1. The system 20 comprises an upper mould part 2 and a lower mould part 3 configured to form a mould comprising a mould cavity 1. An injector 21 having a reservoir 22 filled with for instance water is heated by a heater 23. Water vapor 24 flowing out of the injector 21 is regulated by a valve 25 and enters the mould cavity 1 via the mould cavity entrance opening 4. In the mould cavity 1, the water vapor 24 expels any particles 6 and any gas from the mould cavity 1 through the mould cavity exit opening 5. A first temperature sensor 26 and a second temperature sensor 27 border the mould cavity wall 30. A difference between registered temperatures by the temperature sensors 26, 27 is fed to a controller 28, which in turn adjusts the operation of the heater 23 and/or the valve 25 to provide an optimal flow and temperature of pre-conditioning gas 24 for equalization the temperature the mould cavity wall 30 at a desired level.

1. A method for pre-conditioning the temperature of a mould cavity of a mould for encapsulating electronic components, comprising the method steps:
A) providing a mould for encapsulating electronic components comprising a mould cavity with a mould cavity wall, and
B) injecting a temperature pre-conditioning gas into the mould cavity,
wherein a ratio between a total volume of the injected temperature pre-conditioning gas and the total volume of the mould cavity is at least 1:1, and
wherein the temperature of the temperature pre-conditioning gas prior to injecting the temperature pre-conditioning gas into the mould cavity is controlled to change the temperature of the mould cavity wall due to controlled temperature exchange with the temperature pre-conditioning gas to a desired temperature level.

2. The method according to claim 1, wherein the total gas volume of the temperature pre-conditioning gas injected in the mould cavity is controlled to change the temperature of the mould cavity wall with the temperature pre-conditioning gas to a desired temperature level.

3. The method according to claim 1, wherein the feed rate of the temperature pre-conditioning gas injected in the mould cavity is controlled to change the temperature of the mould cavity with the temperature pre-conditioning gas in a controlled time-frame to a desired temperature level.

4. The method according to claim 1, wherein the temperature pre-conditioning gas has a temperature of at least 50 °C, preferably at least 100 °C, more preferably at least 125 °C, even more preferably at least 150 °C, most preferably between 150 °C and 200 °C.

5. The method according to claim 1, wherein the pre-conditioning gas is a condensable gas.

6. The method according to claim 1, wherein the ratio between the total volume of the injected temperature pre-conditioning gas and the total volume of the mould cavity is at least 5:1, preferably at least 10:1, more preferably at least 20:1, and most preferably at least 30:1.

7. The method according to claim 1, wherein prior to injecting the pre-conditioning gas, a temperature difference between the temperature pre-conditioning gas and the mould cavity wall is less than 100 °C, preferably less than 50 °C, more preferably less than 20 °C, most preferably less than 5 °C.

8. The method according to claim 1, wherein the temperature change of the mould cavity wall is such that the resulting temperature is substantially homogeneously distributed over the wall surface.

9. The method according claim 1, wherein the mould cavity is substantially closed and at least one electronic component carried by a substrate is allocated in the mould cavity before the temperature pre-conditioning gas contacts the cavity wall.

10. The method according to claim 9, wherein the temperature pre-conditioning gas is fed into the mould cavity though a mould cavity entrance opening and at least partly exits the mould cavity through a mould cavity exit opening.

11. The method according to claim 1, wherein a contact time of the temperature pre-conditioning gas and at least part of the wall of the mould cavity is at least 0.1 second, preferably at least 0.5 seconds, more preferably at least 1 seconds, even more preferably at least 2 seconds, most preferably at least 5 seconds.

12. The method according to claim 1, wherein a temperature of at least part of the mould cavity wall is measured at at least two different locations providing at least two temperature measurements, and
wherein the contact time of the temperature pre-conditioning gas and the mould cavity wall is controlled based on the temperature measurements.

13. A moulding system for temperature pre-conditioned encapsulating electronic components mounted on a carrier, comprising:
at least one mould with at least two mould parts which are displaceable relative to each other, at least one of the mould parts with a mould cavity recessed in a contact side, which mould parts are configured to engage with the mould cavity around the electronic components to be encapsulated; and
a temperature pre-conditioning gas injector connecting to the mould cavity,
wherein the system is suitable for carrying out the method according to claim 1.

14. The system according to claim 13, comprising at least two temperature sensors located in the mould cavity wall.

15. The system according to claim 13, comprising a heater for heating the injector fed pre-conditioning gas.

16. The system according to claim 13, comprising a controller for controlling the volumetric flow rate and/or temperature of the temperature pre-conditioning gas injector.
